(19) United States
(12) Patent Application Publication
(10) Pub. No.: US 2009/0246963 A1
(43) Pub. Date: Oct. 1, 2009

(54) Exposure Apparatus Applying Polarization Illuminator and Exposure Method Using the Same

(75) Inventor: Hyun Jo Yang, Chungcheongbuk-do (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/345,383

(22) Filed: Dec. 29, 2008

(30) Foreign Application Priority Data
Mar. 27, 2008 (KR) 10-2008-0028630

(51) Int. Cl. H01L 21/027; H01L 21/00

(52) U.S. Cl. 438/708; 430/311; 257/E21.023

(57) ABSTRACT

An exposure apparatus for transferring patterns on a phase shift mask into a wafer according to the present invention comprises a light source, a polarized light illuminator that selectively passes through a TM mode polarized light of light from the light source to cause it to be incident onto the phase shift mask, a polarization mode translator that translates the TM mode polarized light passing through the phase shift mask into TE mode polarized light, and a lens system irradiating the TE mode polarized light from the polarization mode translator on the wafer.

### CROSS-REFERENCE TO RELATED APPLICATIONS

Priority to Korean patent application number 10-2008-0028630, filed on Mar. 27, 2008, the disclosure of which is incorporated by reference in its entirety, is claimed.

### BACKGROUND OF THE INVENTION

The present invention relates generally to an exposure apparatus and an exposure method for manufacturing semiconductor devices, and more particularly, to an exposure apparatus applying a polarization illuminator and an exposure method using the same.

Semiconductor devices have a plurality of patterns formed on a wafer. Such patterns are often formed using photolithography technology. Specifically, a photoresist film is formed on a film to be patterned over the wafer. Further, the photoresist is exposed to light using a photo-mask, and thereafter a part of the surface of the film to be patterned is exposed by developing the exposed photoresist to form the photoresist film patterns. Subsequently, the patterns are formed on the wafer by removing the exposed part of the film to be patterned by means of an etch process using the photoresist film patterns as an etch mask. Recently as the integration of the semiconductor device increases, the size of the patterns formed on the wafer is gradually becoming smaller, and as a result, it is difficult to form precise patterns in view of the exposure apparatus and the exposure method.

Various methods are proposed and applied for forming finer patterns by improving exposure resolutions and one of them is to increase a lens aperture of the exposure apparatus. However, if the lens aperture is greater than a certain size, an angle at which the light irradiated on the wafer is diffracted after passing through the photo-mask is increased, thereby causing an attenuated interference. Therefore, a polarization illuminator is used, which is capable of removing the light of the polarized light in the direction in which the attenuated interference occurs, in order to remove such attenuated interference. Since the attenuated interference phenomenon typically occurs in a TM polarization mode, a TE polarization mode illuminator is generally used.

In the meantime, as the patterns are becoming finer, the distance between the patterns on the photo-mask is less than the wavelength of the illuminating light, and the pattern on the photo-mask functions as a grating so that the photo-mask itself can serve as a polarizing plate. As an example, in a case that chrome film patterns are a binary photo mask formed as light isolation patterns, the TE polarization mode dominantly functions as the polarizing plate when the size of the patterns to be formed on the wafer is greater than 20 nm, and the TM polarization mode dominantly functions as the polarizing plate when the size of the patterns to be formed on the wafer is less than 20 nm. Therefore, since a transmittance of the TE polarization is not reduced for the size greater than 20 nm, it can be used without a great problem. However, in a case of a phase shift mask, which is more suitable for forming fine patterns since it can achieve greater resolution than the binary photo-mask, the TM polarization mode is dominant and the transmittance of the TE polarization is considerably reduced when the size of the patterns to be formed on the wafer is below 50 nm. In other words, when fine patterns having a size less than 50 nm are to be formed on the wafer, the transmittance of the TE polarized light passing through the phase shift mask is considerably reduced due to the patterns on the phase shift mask, and as a result, the usage efficiency in the polarization illuminator of the TE polarization mode is considerably reduced. Therefore, if fine patterns having a size less than 50 nm are to be formed on the wafer, the polarization illuminator of the TE polarization mode can not be used together with the phase shift mask, but the binary photo-mask (which has lower resolution) is used instead of the phase shift mask.

### SUMMARY OF THE INVENTION

Embodiments of the present invention are directed to an exposure apparatus and an exposure method using the same which are allowed to form finer patterns less than 50 nm using a phase shift mask together with a polarization illuminator.

In one embodiment according to the present invention, an exposure apparatus for transferring patterns on a phase shift mask into a wafer comprises a light source, a polarized light illuminator that selectively passes through a TM mode polarized light of light from the light source to cause the TM mode polarized light to be incident onto the phase shift mask, a polarization mode translator that translates the TM mode polarized light passing through the phase shift mask into TE mode polarized light, and a lens system that irradiates the TE mode polarized light from the polarization mode translator onto the wafer.

The polarization mode translator may comprise a ¼λ wave plate.

The phase shift mask may comprise an attenuated phase shift mask.

An exposure method for transferring patterns on a phase shift mask onto a wafer according to the present invention comprises a step of causing a TM mode polarized light to be incident onto the phase shift mask, and a step of translating the TM mode polarized light passing through the phase shift mask into a TE mode polarized light, to allow it to be irradiated on the wafer.

The step of translating the TM mode polarized light into the TE mode polarized light may be performed using a polarization mode translator with a ¼λ wave plate.

The phase shift mask may comprise an attenuated phase shift mask.

The apparatus and method are contemplated to include embodiments including any combination of one or more of the additional optional elements, features, and steps further described below (including those shown in the figures), unless stated otherwise.

### BRIEF DESCRIPTION OF THE DRAWINGS

FIG. 1 is a schematic view showing an exposure apparatus applying a polarization illuminator according to an example of the present invention.

FIG. 2 is a graph showing a polarization property according to a pattern on a phase shift mask.

### DESCRIPTION OF SPECIFIC EMBODIMENTS

Hereinafter, an exposure apparatus and an exposure method in accordance with the present invention will be described in detail with reference to the accompanying drawings.

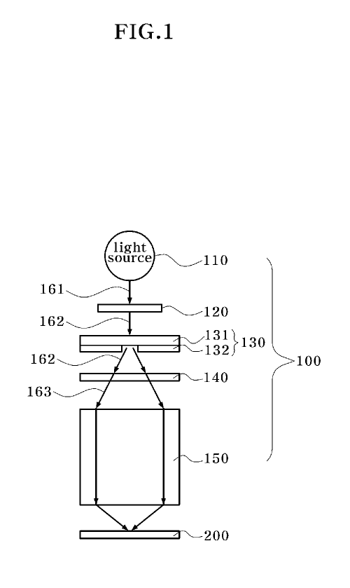

FIG. 1 is a schematic view showing an example of the exposure apparatus applying the polarization illuminator according to the present invention. Referring to FIG. 1, the exposure apparatus 100 includes a light source 110 generating the light 161, a polarization illuminator 120 passing only one direction light, i.e., TM mode polarized light 162 of the light 161 emitted from the light source 110, a phase shift mask PSM 130 selectively transmitting the TM mode polarized light 162 passing through the polarization illuminator 120, a polarization mode translating plate 140 translating the TM mode polarized light 162 into TE mode polarized light 163, and a lens system 150 delivering the TE mode polarized light 163 passing through the polarization mode translating plate 140 to the wafer 200.

The light source 110 generates the light 161 of certain wavelength, and may be, but not limited to, a KrF light source having a wavelength of 248 nm or an ArF light source having a wavelength of 193 nm. Although not shown in the drawing, the light source 110 may include an illuminator, which may be a conventional illuminator or a varied illuminator such as an off-axis illuminator. The polarization illuminator 120 intercepts the TE mode polarized light and passes only the TM mode polarized light 162 in the light 161 emitted from the light source 110. The phase shift mask 130 is constructed with the phase shift film patterns 132 being arranged on the transparent substrate 131. Particularly, the phase shift mask 130 may be an attenuated PSM having phase inverted and amplitude attenuated in the light blocking area. The polarization mode translating plate 140 receives the TM mode polarized light 162 and translates and emits it to the TE mode polarized light 163. The polarization mode translating plate 140 preferably includes a quarter wave (¼λ) wave plate for translating the polarization mode. The ¼λ wave plate shifts the wavelength of the incident polarized light by 90°, to cause it to be converted into polarized light oscillating in a direction vertical to (parallel to) the oscillation direction of the incident polarized light. The lens system 150 delivers the TE mode polarized light 163 changed by the polarization mode translating plate 140 to the wafer 200.

Specifically explaining the exposure method using such exposure apparatus, as the light 161 emitted from the light source 110 passes through the polarization illuminator 120, only the TM mode polarized light is delivered to the phase shift mask 130. If the patterns to be formed on the wafer 200 are finer patterns less than 50 nm, the size of the phase shift film patterns 132 of the phase shift mask 130 are also reduced, and particularly if the distance between the phase shift film patterns 132 is less than the wavelength of the light 161 emitted from the light source 110, the phase shift film pattern 132 itself functions as the polarizing plate.

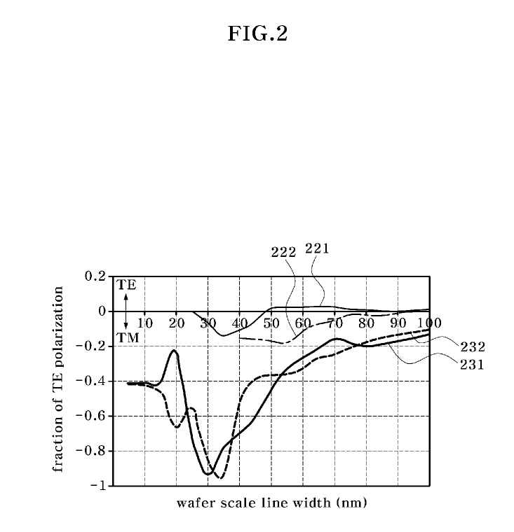

FIG. 2 is a graph showing the polarization property according to the patterns on the phase shift mask. In FIG. 2, the horizontal axis indicates wafer scale line width in units of nm, and the vertical axis indicates the fraction of the TE mode polarized light. Therefore, in the vertical axis, positive integers indicate TE mode polarized light and negative integers indicate TM mode polarized light. The line referred to by reference numeral “221” indicates first order light if the light is incident at an angle of 00, the line referred to by reference numeral “222” indicates first order light if the light is incident at an angle of 200, the line referred to by reference numeral “231” indicates zeroth order light if the light is incident at an angle of 0°, and the line referred to by reference numeral “232” indicates zeroth order light if the light is incident at an angle of 20°. As shown in FIG. 2, it will be appreciated that the transmittance of the TE mode polarized light is higher if the line width of the wafer is greater than 50 nm, whereas the transmittance of the TM mode polarized light is higher if the line width of the wafer is less than 50 nm. Therefore, when forming fine patterns having a line width less than 50 nm, the TM mode polarized light from the polarized light illuminator 120 passes through the phase shift mask 130 by a sufficient amount.

As such TM mode polarized light 162 is irradiated on the wafer 200, the attenuated interference occurs and, as a result, the photoresist film on the wafer 200 can not be correctly exposed as designed due to the attenuated interference. Therefore, the TM mode polarized light 162 is translated into TE mode polarized light 163 by disposing the polarization mode translating plate 140 between the phase shift mask 130 and the wafer 200 such as in the present invention. As earlier mentioned, the polarization mode translating plate 140 includes ¼λ wave plate, and the TM mode polarized light 162 is translated into TE mode polarized light 163 by such ¼λ wave plate. Since the TE mode polarized light 163 does not induce attenuated interference, the light is irradiated on the wafer via the lens system 150 without attenuated interference.

According to the present invention, even though forming the fine patterns having a line width less than 50 nm using a phase shift mask, which is known to provide resolution superior to a binary photo mask, it is possible to form fine patterns in high resolution without attenuated interference by translating the TM mode polarized light into TE mode polarized light after passing it through the phase shift mask and before irradiating it on the wafer.

While the present invention has been described with respect to the specific embodiments, it will be apparent to those skilled in the art that various changes and modifications may be made without departing from the spirit and scope of the invention as defined in the following claims. Throughout the specification, where apparatus and methods are described as including components or steps, it is contemplated that the apparatus and methods can also consist essentially of, or consist of, any combination of the recited components or materials, unless described otherwise.

What is claimed is:

1. An exposure apparatus for transferring patterns on a phase shift mask into a wafer, comprising:
a light source;
a polarized light illuminator that selectively passes through TM mode polarized light of light from the light source to cause the TM mode polarized light to be incident onto a phase shift mask;
a polarization mode translator that translates the TM mode polarized light passing through the phase shift mask into TE mode polarized light; and
a lens system that irradiates the TE mode polarized light from the polarization mode translator onto the wafer.

2. The apparatus of claim 1, wherein the polarization mode translator comprises a ¼λ wave plate.

3. The apparatus of claim 1, wherein the phase shift mask is an attenuated phase shift mask.

4. An exposure method for transferring patterns on a phase shift mask onto a wafer, comprising steps of:
causing TM mode polarized light to be incident onto a phase shift mask;
translating the TM mode polarized light passing through the phase shift mask into TE mode polarized light; and
directing the TE mode polarized light onto a wafer.

5. The method of claim 4, comprising emitting light from a light source through a polarized light illuminator that selectively passes through TM mode polarized light of light from the light source, to obtain the TM mode polarized light.

6. The method of claim 4, comprising translating the TM mode polarized light into TE mode polarized light using a polarization mode translator with a ¼λ wave plate.

7. The method of claim 4, wherein the phase shift mask comprises an attenuated phase shift mask.
